(19) United States
(12) Patent Application Publication
(10) Pub. No.: US 2010/0310788 A1
(43) Pub. Date: Dec. 9, 2010

(54) METHOD AND SYSTEM FOR CONTINUOUS OR SEMI-CONTINUOUS LASER DEPOSITION

(75) Inventors: Franciscus Cornelius Dings, Eindhoven (NL); Woutherus Johannes Maria Brok, Eindhoven (NL)

Correspondence Address: PILLSBURY WINTHROP SHAW PITTMAN, LLP, P.O. BOX 10500, MCLEAN, VA, 22102, US

(73) Assignee: OTB GROUP B.V., Eindhoven (NL)

(21) Appl. No.: 12/743,757

(22) PCT Filed: Nov. 21, 2008
(86) PCT No.: PCT/NL08/50736

§ 371 Date: Aug. 11, 2010

(30) Foreign Application Priority Data
Nov. 21, 2007 (EP) 07121181.7

(51) Int. Cl. H05H 1/24; C23C 8/02; C23C 16/00; B05C 11/00

(52) U.S. Cl. 427/569; 427/586; 118/723 R; 118/712; 118/708

(57) ABSTRACT

The invention relates to a method for deposition of material by laser evaporation wherein the employed laser is a continuous or semi-continuous laser. Using such a laser, it is possible to evaporate the target material in a controlled manner from a local pool of liquid or fluidized target material at the target surface. The invention also provides a system for executing said method.

The invention relates to a method and a system for deposition of material by laser evaporation. The method comprises providing a first laser, providing a deposition chamber, providing a target of substantially laser evaporative material in said deposition chamber, providing a substrate in said deposition chamber, evacuating said deposition chamber to sub-atmospheric pressure, operating said first laser to direct a first beam of laser light at said target so as to form a cloud of laser evaporated material, placing said substrate at least partially within said cloud of laser evaporated material, and depositing said laser evaporated material on said substrate.

Such a method is known from for example US 2004/0033702-A1. A problem associated with the known method is the relatively low level of control over the ablation process, which prevents the formation of high quality thin films. For example, during laser ablation of a target according to the known method, a plume of laser ablated target material is produced comprising particulates that, ideally, should not be produced, much less be deposited on the substrate as they have a negative effect on the quality of the film. To prevent the deposition of said particulates on the substrate, US 2004/0033702-A1 uses a rotating target to impart a predetermined component of velocity to the ablated material, such that the heavier, slower moving evaporants deflect from the propagation direction and are prevented from being deposited on the substrate. Although this specific example, which is indicative of the low degree of control over the ablation process, can be dealt with this way, it is obviously preferable to employ a method of laser deposition that does not produce any particulates in the first place.

An objective of the present invention is therefore to provide a method for deposition of material by laser evaporation that allows for a higher degree of control over the ablation process than that provided by the known method.

To this end the invention provides a method according to the above-mentioned type, characterized in that said first laser is a continuous or semi-continuous laser, wherein a semi-continuous laser is a pulsed laser having a pulse frequency <1 kHz and a pulse width of at least 0.0001 s.

The known method of laser deposition, which is often referred to as pulsed laser deposition (PLD), employs a pulsed laser that produces relatively short light pulses having a pulse duration on the order of nanoseconds, picoseconds or even shorter durations. As all or at least the larger part of the energy necessary to ablate the target material is transferred to the target material by means of these relatively short laser pulses, the laser pulses commonly have a relatively high energy content. Consequently, laser ablation at the surface of the target material takes places under rather violent circumstances, including high temperatures and pressures, and steep gradients thereof. The train of intense high power laser pulses striking the target material may cause the decomposition of the molecular structure of a target material, and/or the sublimation of target material (i.e. gasification of material directly from its solid state) whereby particulates, which ideally are not present in a plume of ablated material, are detached from the target. Furthermore, the violent nature of pulsed laser deposition may interfere with an accurate and stable deposition rate. To gain a better control over the ablation process and the composition of the cloud of ablated material, the method according to the invention uses a laser that transfers energy onto the target either continuously or semi-continuously. Such a laser emits its energy at a lower power than the pulsed laser used in the known method described above. It is therefore less likely to decompose the molecular structure of the target material, or to sublimate the target. Through the use of a continuous or semi-continuous laser a so called ‘melt’ is created at the surface of the target: a local pool of liquid or fluidized target material from which pool said material can be evaporated in a well controlled manner by supplying energy to it. The method according to the invention thus contemplates an ablation process, whereby the target material is first brought into a liquid or fluidized state, from which it is subsequently evaporated. Accurate control over the rate of evaporation of target material from the melt can, for example, be exercised by changing the pulse width and/or pulse frequency of a semi-continuous laser, or changing the wave length of the laser light. The above described method is widely applicable. It can be used to laser deposit any material that can be laser evaporated, such as for instance metals or semi-conductors like silicon.

According to a further aspect of the invention, the method according to the invention further comprises providing a gas atmosphere in said deposition chamber.

By providing a gas atmosphere, elements other than the target material may be incorporated into the deposited material and/or films. Molecules and/or atoms of a so called precursor gas may, for example, react chemically with the laser evaporated material of the target, either before the target material is deposited or at the substrate after deposition. This is even true despite the high growth rates attained by laser induced evaporation deposition. Reactive gases may also be used to eliminate contaminating material from the deposition chamber. For example, a scavenger gas such as silane (SiH4) may be used to effectively eliminate any oxygen (O2), which may interfere with the deposition process by oxidizing deposited material. Also non-reactive gases can be useful, for example to reduce the influence of residual gasses (such as water vapour and oxygen) still present in the deposition chamber after evacuation, to facilitate diffusion of the laser evaporated material, and/or to control the dimensions of the cloud of laser evaporated material by changing the pressure of the gas atmosphere inside the deposition chamber.

According to a further elaboration of the invention, said gas atmosphere is a hydrogen gas atmosphere.

A hydrogen gas atmosphere can be particularly useful when the target material to be deposited is to be hydrogenated. Such may for example be the case when amorphous silicon (a-Si) films are produced, in order to reduce the dangling bond density.

According to a further elaboration of the invention, the method according to the invention further comprises providing means for decomposing at least part of the gas comprised by the gas atmosphere into a plasma, and operating said means so as to cause the decomposition of said at least part of the gas into a plasma.

Although an initially non-reactive gas present in the deposition chamber may sometimes be activated through, for example, the temperature of the cloud of laser evaporated material, it may—under circumstances—be necessary or desirable to activate a gas by other means. A plasma—a highly (re)active form of the gas—may be created in many ways, such as through the use of a magnetron, an ICP (inductively coupled plasma)-source, or a pair of electrodes across which a possibly alternating electrical potential difference is applied by means of a controllable power supply. By choosing the background gas and the gas decomposition means appropriately, the kind and the amount of reactive particles present in the deposition chamber can be controlled, and therewith the composition and characteristics of the deposited material. In case the gas decomposition means comprise one or more electrodes, it is relatively easy to ensure that the plasma is present in at least the direct environment of either the target or the substrate. This may, for instance, be achieved by providing the target, respectively the substrate, with a carrier for positioning the element, whereby the carrier also serves as an electrode so as to electrically bias the target or the substrate. By electrically biasing an element, i.e. providing the element with a certain electrical potential relative to its surroundings, particles from a gas or plasma may be attracted towards the element in order to impact on, to be deposited on, or to chemically react with the element. It is noted that, to achieve this effect, it is not necessary that an electrode is physically connected to the element or the substrate or target carrier. It may be sufficient to provide a biased electrode in the vicinity of the element, such as behind it.

According to a further elaboration of the invention, the method according to the invention further comprises providing a second laser, and operating said second laser to direct a second beam of laser light at said target so as to preheat at least a partial surface area of said target.

By means of two lasers the level of control over the evaporation process can be improved. An auxiliary laser, i.e. the second laser, can be used to preheat the target surface up around for example its melting point or evaporation temperature, whereafter evaporation of the target material can be induced by the first laser. An advantage of this two-step process is that the first laser can be configured to emit its energy at parameters (such as pulse duration, pulse width, pulse height and/or wave length) tailored to the deposition process at hand, and at a relatively low power, thus allowing for very accurate control over the temperature of the target surface. The auxiliary laser may preheat the target surface in several ways, such as by means of line-illumination—through the use of an extra optical element—or by means of a scanning movement of a laser beam over the target surface.

According to a further elaboration of the invention, the method for deposition of material by laser evaporation according to the present invention can be used for manufacturing a thin film solar cell.

The high quality thin films that can be produced using the method according to the invention may be applied in thin film solar cells. The method is fit for the production of both single—as well as multi-layer films of varying thicknesses and surfacial dimensions.

Further elaborations of the invention are described in the claims and in the description of the figures below.

### FIGURES

FIGS. 1 and 2 schematically show a side view, respectively a frontal view, of a system for laser deposition according to the invention.

### DESCRIPTION OF THE FIGURES

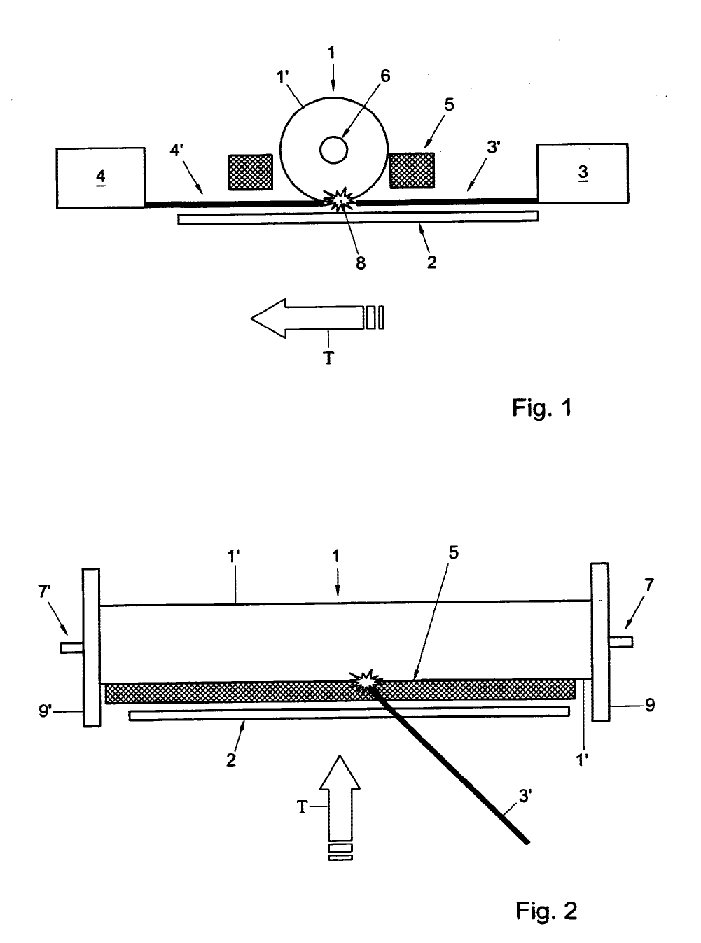

FIGS. 1 and 2 show a system for laser deposition according to the invention. The figures show the following elements: a cylindrical target 1, said target 1 having a target surface 1′ which may be provided with an interior fluid channel 6, said fluid channel 6 having end connectors 7 and 7′; a substrate 2 moving in a transport direction T; a first continuous or semi-continuous laser 3 emitting a beam of laser light 3′; a second laser 4 emitting a beam of laser light 4′; a gas or plasma atmosphere 5, a cloud of laser evaporated material 8, and two shields 9, 9′. The aforementioned target 1, substrate 2 and gas or plasma atmosphere 5 are all located inside a deposition chamber (not shown as such), which is evacuated to sub-atmospheric pressure by a pump (not shown). The lasers 3, 4 are not necessarily located inside the deposition chamber; they may also be located outside the deposition chamber, whereby the produced beams of laser light 3′, 4′ travel through one or more transparent windows into the deposition chamber. A such transparent window may, for example, be made of quartz. Because of the high temperatures to which a such window is exposed in use, it may advantageously possess self-cleaning properties with regard to parasitic deposition.

To evaporate target material off a target 1, two lasers 3, 4 are used. The second laser 4, i.e. the auxiliary laser, is employed to preheat at least a patch of target surface 1′ up to a certain temperature, such as a temperature around the melting or evaporation point of the target material. Subsequently, the first laser 3 is employed to accurately induce evaporation of the target material at said patch of target surface 1′. Care is taken to ensure that the target material is controllably evaporated from a melt, i.e. a region of the target surface 1′ comprising liquid or fluidized target material. To this end, the first laser operates either continuously or semi-continuously at a pulse frequency <1 kHz and with a pulse width of at least 0.0001 s. The wave length of the laser is preferably in the range of 0.3 μm-15 μm, more preferably in the range of 0.8 μm-12 μm. This combination of parameters ensures a continuous or at least a semi-continuous transfer of energy onto the target, whereby the power at which the energy is transferred is neither too high nor too low, and appropriate for most deposition applications. Based on, for example, the specific target material chosen, the parameters may be optimized within the given ranges. In the case of a silicon target, for instance, a wave length of about 1 μm may be advantageous as silicon tends to absorb energy supplied at or around this wave length relatively well. The first laser 3 and the second laser 4 are operated in cooperation. The produced beams of laser light 3′, 4′ may thereby perform a complementary scanning movement over the target surface 1′, along the longitudinal axis of the cylindrical target 1. Alternatively, the second laser 4 may be used in a non-scanning manner. Through the use of an extra optical element, for example, the second laser 4 may be used to provide a line illumination on the target 1, such that the illuminated surface part of the target is preheated and fluidized, and an elongated melt is created. The first laser 3 may then subsequently scan along said elongated melt provided on the target surface in order to evaporate the preheated target material. It is noted that although this embodiment shows two lasers 3, 4, a different embodiment using only one laser 3 may provide the effect of the invention as well.

To realize uniform evaporation of the target 1, said target 1 is rotated around its longitudinal axis. The length of the target 1 has been made to correspond approximately to the width of the substrate 2, as is clearly shown in FIG. 2. By moving the substrate 2 along a transport direction T perpendicular to the axis of the target 1, a layer of target material can be deposited onto the whole deposition surface of said substrate 2. An advantage of the setup shown in FIGS. 1 and 2 is that the so called parasitic deposition, i.e. deposition of target material onto places other than the substrate 2, is limited. The distance between the substrate 2 and the target surface 1′, and the dimensions of the substrate 2 relative to the dimensions of the cloud of laser evaporated material 8, are chosen such that any evaporated material will quickly come into contact with substrate 2, to which it will adhere. Typically, the distance between the target surface part at which the laser or lasers impact the target and the substrate surface part which is most adjacent to that target surface part is in the range of 0.5-5 mm. To further minimize parasitic deposition and contamination of the deposition chamber, shields 9, 9′ may be attached to the extremities of the target, so as to confine the cloud of laser evaporated material 8. Advantageously, the shields 9, 9′ also contribute to an efficient use of target material, as target material incidentally deposited onto the shields may be reintroduced into the cloud of evaporated material 8 due to the environmental conditions at the surface of the shields.

It is noted that the substrate 2 may be subject to high temperatures, and should therefore be made of heat resistant material, such as glass. High substrate temperatures may, for example, result from contact with the cloud of laser evaporated material 8, the gas or plasma 5, or from direct heating of the substrate by a heating device (not shown). Heating by a heating device may, for example, be advantageous in cases where laser evaporated material does not adhere adequately to a substrate with a too low temperature, or in cases where the thermal motion of the deposited material is necessary to achieve a film with the desired structure. The target 1 may also be subject to high temperatures. To prevent the target 1 from overheating, it may be provided with an interior fluid channel 6, through which a cooling fluid circulates. Alternatively, the interior fluid channel 6 may be used to preheat the target 1 by circulating a heating fluid through it. The substrate and/or the target may be provided with a temperature sensor—possibly at a distance from the substrate and/or target, such as in the case of a pyrometer—, which sensor outputs a sensor signal to a control device that, based on this input, can monitor and control the respective temperature by controlling, for instance, the flow of fluid through the interior fluid channel or the parameters of the first or second laser. Likewise, the deposition chamber may be provided with a pressure sensor.

Although the invention is described above with respect to a certain embodiment, it is understood that one skilled in the art can apply various changes and adaptations without leaving the scope of the present invention as defined by the claims.

1. A method for laser deposition comprising:
evacuating a deposition chamber to sub-atmospheric pressure;
operating a first laser to direct a first beam of laser light at a target of substantially laser evaporative material so as to form a cloud of laser evaporated material; and
depositing said laser evaporated material on a substrate
wherein said first laser is a continuous or semi-continuous laser, the semi-continuous laser being a pulsed laser having a pulse frequency less than 1 kHz and a pulse width of at least 0.0001 s.

2. The method according to claim 1, wherein laser light produced by the first laser comprises one or more wave lengths in the range of 0.3 μm-15 μm.

3. The method to claim 1, further comprising:
supplying a gas atmosphere in said deposition chamber.

4. The method according to claim 3, wherein the gas atmosphere is a hydrogen gas atmosphere.

5. The method according to claim 3, further comprising:
decomposing at least part of the gas comprised by the gas atmosphere into a plasma,

6. The method according to claim 5, wherein decomposing gas into a plasma applying an appropriate electrical potential difference to two electrodes using a controllable power supply connected to said electrodes.

7. The method according to claim 6, wherein one of said electrodes, or a third electrode connected to said controllable power supply, is configured to serve as a substrate—or a target carrier.

8. The method according to claim 1, wherein the target of substantially laser evaporative material comprises a substantially cylindrical target.

9. The method according to claim 1, wherein said substantially laser evaporative material is silicon.

10. The method according to claim 1, wherein said substrate comprises a heat resistant substrate.

11. The method according to claim 1, wherein the target of laser evaporative material comprises a target with an interior fluid channel, and the method further a comprises flowing fluid through said interior fluid channel so as to control the temperature of said target.

12. The method according to claim 1, further comprising:
heating said substrate using a heating device while depositing said laser evaporated material on said substrate.

13. The method according to claim 1, further comprising redirecting said first beam of laser light incident on a partial surface area of said target so as to continuously change the partial surface area of said target being exposed to said first beam of laser light.

14. The method according to claim 1, further comprising moving said target relative to said first beam of laser light incident on a partial surface area thereof so as to continuously change the partial surface area of said target being exposed to said first beam of laser light.

15. The method according to claim 13, whereby said first beam of laser light is redirected along a first direction, and whereby said target is rotated around an axis that extends in a second direction that is substantially parallel to said first direction.

16. The method according to claim 1, further comprising moving said substrate, at least partially, through said cloud of laser evaporated material so as to distribute the deposition of said material over a deposition surface of said substrate in order to grow a film of said material on said deposition surface.

17. The method according to claim 15, whereby said target is rotated around an axis that extends in a third direction, and whereby said substrate is moved along a fourth direction that is substantially perpendicular to said third direction.

18. The method according to claim 1, further comprising:
operating a second laser so as to preheat a partial surface area of said target.

19. The method according to claim 18, wherein the first laser and the second laser are operated in cooperation, whereby the second laser is operated to preheat a partial surface area of said target, and whereby the first laser is scanningly directed at said partial surface area so as to evaporate the preheated target material.

20. A method for manufacturing a thin film solar cell according to the method of claim 1.

21. A laser deposition apparatus comprising:
a first laser wherein said first laser is a continuous or semi-continuous laser, the semi-continuous laser being a pulsed laser having a pulse frequency less than 1 kHz and a pulse width of at least 0.0001 s;
a deposition chamber configured to deposit a laser evaporated material on a substrate, said deposition chamber comprising at least one channel through which matter can be supplied to and/or discharged from the deposition chamber, a target of substantially laser evaporative material, said target being located in said deposition chamber; and
a pump for evacuating the deposition chamber, said pump being connectable to a said channel of the deposition chamber.

22. The apparatus according to claim 21, wherein said first laser produces light comprising one or more wave lengths in the range of 0.3 μm-15 μm.

23. The apparatus according to claim 21, further comprising a gas supply for providing a gas atmosphere inside the deposition chamber.

24. The apparatus according to claim 23, further comprising means for decomposing the gas comprised by the gas atmosphere into a plasma.

25. The apparatus according to claim 24, wherein said means for decomposing the gas into a plasma comprise two electrodes and a controllable power supply connected thereto.

26. The apparatus according to claim 25, wherein one of said electrodes, or a third electrode connected to said controllable power supply, is configured to serve as a substrate—or a target carrier.

27. The apparatus according to claim 21, wherein said target of substantially laser evaporative material is substantially cylindrical.

28. The apparatus according to claim 21, wherein said laser evaporative material is silicon.

29. The apparatus according to claim 21, wherein said substrate is comprised of a heat resistant material.

30. The apparatus according to claim 21, wherein said target of laser evaporative material comprises an interior fluid channel for circulation of a temperature control fluid.

31. The apparatus according to claim 21, further comprising a heating device for heating said substrate.

32. The apparatus according to claim 21, wherein said apparatus is configured to make a first laser beam produced by said first laser perform a scanning movement over a surface of said target, while evaporating said surface.

33. The apparatus according to claim 21, further comprising means for rotating said target around at least one axis.

34. An apparatus according to claim 21, further comprising means for translationally moving said substrate along at least one direction.

35. The apparatus according to claim 21, further comprising a second laser for cooperation with said first laser, wherein said second laser is operated to preheat at least a partial surface area of said target.

36. The apparatus according to claim 21, further comprising at least one sensor for measuring
(i) a temperature of the substrate,
(ii) a temperature of the target or
(iii) the pressure in the deposition chamber.

37. The apparatus according to claim 36, further comprising a control device for controlling
(i) the temperature of the substrate, based on informational input from a substrate temperature sensor,
(ii) the temperature of the target, based on informational input from a target temperature sensor, or
(iii) the pressure in the deposition chamber, based on informational input from a deposition chamber pressure sensor.

38. A method for laser deposition comprising:
evacuating a deposition chamber to sub-atmospheric pressure;
operating a laser to direct a beam of laser light at a substantially cylindrical target of substantially laser evaporative material so as to form a cloud of laser evaporated material;
rotating the target relative to the beam of laser light incident on a partial surface area thereof so as to continuously change the partial surface area of the target being exposed to the beam of laser light;
depositing the laser evaporated material on a substrate;
scanningly redirecting the beam of laser light along a direction that is parallel to a longitudinal axis around which the target is rotated; and
translationally moving the substrate, at least partially, through the cloud of laser evaporated material so as to distribute the deposition of the material over a deposition of the substrate in order to grow a film of the material of the deposition surface,
wherein the laser is a continuous or semi-continuous laser, the semi-continuous laser being a pulsed laser having a pulse frequency less than 1 kHz and a pulse width of at least 0.0001 s.

39. A laser deposition apparatus comprising:
a continuous or semi-continuous laser, wherein the semi-continuous laser is a pulsed laser having a pulse frequency less than 1 kHz and a pulse width of at least 0.0001 s;
a deposition chamber configured to deposit a laser evaporated material on a substrate, the deposition chamber comprising at least one channel through which matter can be supplied to and/or discharged from the deposition chamber,
a substantially cylindrical target of substantially laser evaporative material, said target being located in said deposition chamber;
means for rotating the target around at least one axis so as make a laser beam produced by the laser perform a scanning movement over a surface of the target along a direction that is parallel to the at least one axis around which the target is rotated, the at least one axis being a longitudinal axis of the target;
means for translationally moving the substrate along, at least one direction such that the substrate is movable, at least partially, through a cloud of laser evaporated material so as to distribute the deposition of the material over a deposition surface of the substrate in order to grow a film of the material on the deposition surface; and
a pump for evacuating the deposition chamber, the pump being connectable to a the channel of the deposition chamber.
